(19) United States
(12) Patent Application Publication
(10) Pub. No.: US 2009/0078963 A1
(43) Pub. Date: Mar. 26, 2009

(54) Nano-optoelectronic chip structure and method

(76) Inventor: Salah Khodja, San Bruno, CA (US)

Correspondence Address: Salah Khodja, Apt 2411, 2000 Crystal Springs Rd, San Bruno, CA, 94066, US

(21) Appl. No.: 12/217,669

(22) Filed: Jul. 8, 2008

Related U.S. Application Data
(60) Provisional application No. 60/958,746, filed on Jul. 9, 2007.

(51) Int. Cl. H01L 33/00; G02B 6/12

(52) U.S. Cl. 257/189; 257/458; 385/14; 257/E33.032

(57) ABSTRACT

The present invention relates to integrated structures of III-V and Silicon materials for making optoelectronic devices on chip compatible with complimentary metal oxide semiconductor (CMOS). As a result, various light generation, detection, switching, modulation, filtering, multiplexing, signal manipulation and beam splitting devices could be fabricated in semiconductor material such as silicon on insulator (SOI) and other material substrate.

### CROSS-REFERENCE TO RELATED APPLICATIONS

This application claims priority from provisional application No. 60/958,746 filed on Jul. 9, 2007.

### STATEMENT REGARDING FEDERALLY SPONSORED RESEARCH OR DEVELOPMENT

Not Applicable

### REFERENCE TO A MICROFICHE APPENDIX

Not Applicable

### REFERENCE CITED

Form SB0008a and SB0008b

### BACKGROUND OF THE INVENTION

Optoelectonic circuit technology that allow for compact photonics layer compatible with standard CMOS circuit fabrication will lead to new generation optoelectronic integrated circuit. Integration of more functions on a single opto-electronic chip provides the advantage of the economy of scale, an increase in performance and reliability. Silicon is an attractive material system to fabricate large scale integrated waveguide circuits due to the large refractive index contrast. Moreover, these waveguide structures can be fabricated using standard CMOS processes (1, 2). For optical fiber coupling multiple approaches has been proposed including surface grating coupling (3).

For signal modulation, the prior art work was limited to either a single PIN diode of a single gate MOS structure which require the trade between response speed and efficiency. For example, horizontal PIN diode on silicon like the one on U.S. Pat. No. 6,999,670 and U.S. Pat. No. 7,010,208 suffer from slow speed because of the long gap on the horizontal direction of the waveguide. Vertical PIN provides faster response due to the short vertical gap of the rectangular waveguide with short vertical direction but only single PIN has been explored For particular photonic functions like light generation detection, amplification and signal processing, the InP/InGaAsP material system remains the material of choice, despite significant research in Silicon based active opto-electronic devices Propose approaches on references (4, 5, 6, 7) use wafer glowing with polymer material PCB or wafer bonding and both approaches have issues of reliability and have not been able to address the issues of thermal management. The PCB wafer attachment approach suffer from the fact that the polymer layer is few micron thick and the integration between function in the device is weak and the processes is not repeatable and reliable as required for these application. The wafer bonding approach is a long process that poses a major bottleneck in the fabrication with a very low yield, so far not satisfying the performance and reliability requirement. Santa Barbara University proposed wafer bonding of silicon to III-V material where the optical mode propagate at the interface of the bonding (8), this is a major failure of their approach the interface defect result in high loss and extremely low yield the is worse that the polymer glowing approach proposed by the MEC institute (4).

Prior Art has not been able to provide adequate solution to optoelectronic chip integration so called system in chip (SIC). The invention below provides an original approach of integrating multiple materials on multi-layers structure with very unique and original approach that has not been proposed before. This should improve the process yield reliability and performance of the optoelectronic integrated circuit

### BRIEF SUMMARY OF THE INVENTION

The present invention relates to complementary metal oxide semiconductor (CMOS) structures for making optoelectronic devices on chip compatible with CMOS process.

### FIELD OF THE INVENTION

The present invention relates to integrated structures of III-V and Silicon materials for making optoelectronic devices on chip compatible with complimentary metal oxide semiconductor (CMOS) process.

### BRIEF DESCRIPTION OF THE SEVERAL VIEWS OF THE DRAWING

The accompanying drawings, which are incorporated into and form a part of the disclosure, illustrate embodiments of devices fabricated by the invention and, together with the description, serve to explain the principles of the invention. Drawing are not to scale, has been exaggerated to facilitate understanding of the drawings.

FIG. 1: Perspective view of a novel integrated III-V and Silicon material structure in accordance with the present invention.

FIG. 2: Cross-section view of a novel nano-optoelectronic structure in accordance with the present invention

FIG. 3: Cross section view of III-V material waveguide structure coupled to silicon waveguide structure in accordance with the present invention

FIG. 4: Cross-section view of the novel integrated III-V and silicon material structure in accordance with the present invention

FIG. 5: Cross section view of III-V material waveguide structure coupled to silicon waveguide structure in accordance with the present invention

FIG. 6: Cross section view of III-V material waveguide structure coupled to silicon waveguide structure in accordance with the present invention.

FIG. 7: Cross section view of Integrated III-V material waveguide structure, silicon waveguide structure and CMOS electronic structure in accordance with the present invention

FIG. 8: Cross section view of Integrated III-V material waveguide structure, silicon waveguide structure and CMOS electronic structure in accordance with the present invention

FIG. 9: Cross section view of Integrated III-V material waveguide structure, silicon waveguide structure and CMOS electronic structure in accordance with the present invention

FIG. 10: Cross section view of Integrated III-V material waveguide structure, silicon waveguide structure and CMOS electronic structure in accordance with the present invention

FIG. 11: Perspective view of a novel III-V material waveguide structure and method of fabrication in accordance with the present invention

FIG. 12: Perspective view of a novel III-V material waveguide structure and method of fabrication in accordance with the present invention

FIG. 13: Cross section view of III-V material waveguide structure in accordance with the present invention

FIG. 14: Cross section view of multi-layers III-V material waveguide structure with electrodes coupled to material structure in accordance with the present invention

FIG. 15: Perspective view of another embodiment integration of III-V material waveguide structure coupled to silicon waveguide structure in accordance with the present invention

FIG. 16: Cross section view of III-V material waveguide structure coupled to 3D silicon waveguide structure, in accordance with the present invention

FIG. 17: Perspective view of another embodiment integration of III-V material waveguide structure coupled to silicon waveguide structure in accordance with the present invention

FIG. 18: Perspective view of another embodiment integration of III-V material waveguide structure coupled to silicon waveguide structure in accordance with the present invention

FIG. 19: Integrated III-V material waveguide structure, silicon waveguide structure and CMOS electronic structure in accordance with the present invention

### DETAILED DESCRIPTION OF THE INVENTION

Other objects and advantages of the present invention will become apparent from the following description and accompanying drawings.

Basically the invention involves the fabrication of optoelectronic nano-structures to built components or systems using CMOS compatible process.

The drawings illustrate various optoelectronic nano-structures fabricated by the present invention. The drawings illustrate a variety of embodiments of integrated structures of III-V and Silicon materials for making optoelectronic devices on chip compatible with CMOS process. Thus, the drawings illustrate a variety of applications for the present invention. Reference will now be made in detail to the preferred embodiments of the present invention, examples of which are illustrated in the accompanying drawings.

With reference to the accompanying drawings, the present invention will now be described in detail.

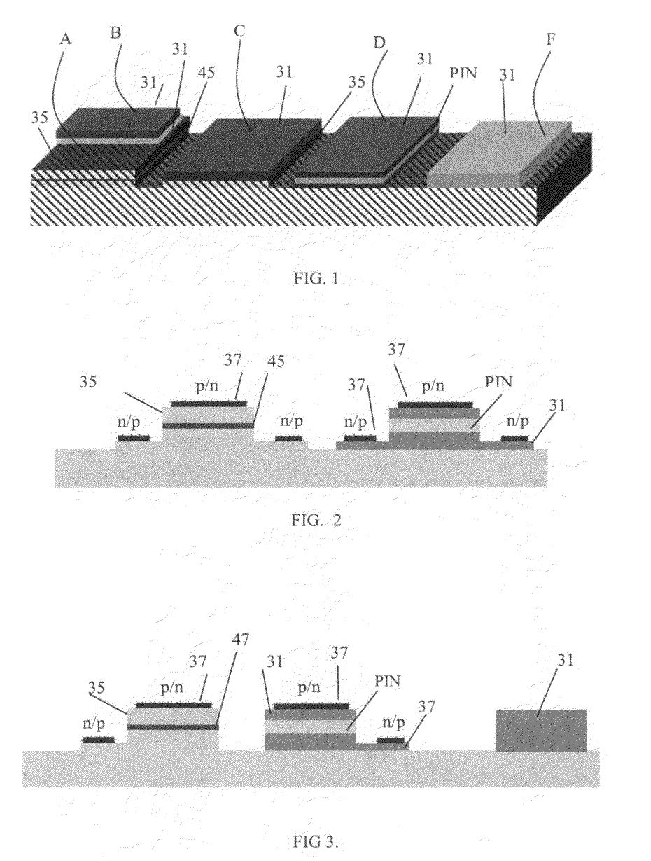

FIG. 1 shows perspective view of a novel heterogeneous material structure, the III-V material structure contains PIN multi-layers structure with quantum wells as shown on section (A). Drawing not to scale to better illustrate sections features. On FIG. 1 sections of the III-V material are etched/removed and one or more layers of heterogeneous materials such as poly silicon are deposited; for instance in section (C) the III-V upper layers including quantum well (45) are etched removed and poly si (31) is grown to form a heterogeneous PIN structure with P layer made of poly silicon and N layer on III-V material or visa versa. In another embodiment of FIG. 1 section (D) the PIN layers of III-V material are removed and multi-layers PIN of poly silicon diode are deposited/gown on the III-V substrate. On section F of FIG. 1 a poly silicon layer (31) is deposited on the III-V substrate (35) which could be used as a passive routing waveguide which could interconnect the PIN structure on multiple sections.

In one embodiment of FIG. 1 section (B) a pair of oxide (30) and poly silicon (31) layers are gown over the III-V PIN structure (A), the oxide layer, section B could be used as a waveguide routing structure to couple light form and to the III-V PIN structure underneath it. The deposited poly-silicon layers eliminate the need for lengthy and low yield of wafer bonding process. The process of deposited layer structures allow for more design flexibility and high yields. The oxide layer thickness can varies from few nanometers to few hundred of nanometer depending on the desired waveguide structure. Few nanometer oxide layer or no oxide layer is suitable for the single waveguide core built from sandwiched III-V and silicon layers. In the case of evanescent coupling between the III-V waveguide and the si waveguide the oxide layer thickness would be around hundreds of nanometers. The silicon waveguide is evanescently coupled to the III-V waveguide structure such as a III-V laser, amplifier etc. The oxide layer can be constitute of one or more of the following oxide material layers, silicon oxide, silicon nitride or oxy-nitride layers to protect and isolate the III-V and silicon materials.

The heterogeneous PIN structure on section (C) could be used to fabricate high speed modulator, photodiode and many other signal processing functions where quantum well is not needed.

FIG. 2 shows a cross section view of a III-V PIN laser diode from section A of FIG. 1 side by side with a poly silicon PIN diode from section D of FIG. 1. The two section waveguide structures are side by side such that same lithography, etch and metallization steps (37) can be used to fabricate both waveguide structures. The III-V PIN waveguide structure could be part of a Fabry Perot (FP) laser cavity of a ring/disk cavity, or simply a non resonant gain waveguide section. Drawing is not to scale to better illustrate waveguide features.

FIG. 3 shows a cross section view of another embodiment of a III-V PIN diode from section A of FIG. 1 side by side with a poly silicon PIN diode from section D of FIG. 1 where the waveguides design and metal electrode configuration (37) is such that it allow for lateral evanescent light coupling between the two PIN waveguide structures. The two section waveguide structures are side by side such that same lithography, etch and metallization steps can be used to fabricate both waveguide structures. A poly-silicon waveguide (31) such on section F could be also built side by side on the same structure

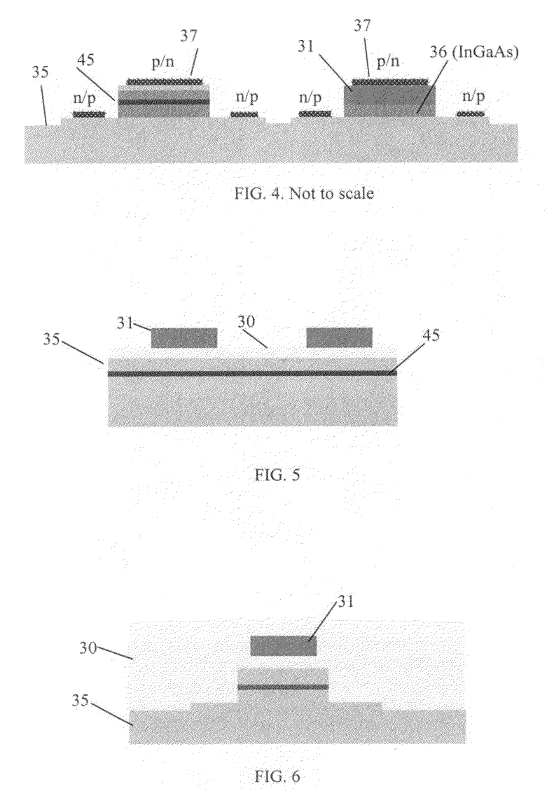

FIG. 4 shows a cross section view of III-V material PIN waveguide structure side by side with heterogeneous PIN waveguide structure in accordance with the present invention. The heterogeneous PIN structure could be for example constituted of InGaAs intrinsic layer (36), P/N layer underneath it (35) and N/P poly silicon layer (31) above it. The heterogeneous PIN structure on section (C) could be used to fabricate high speed modulator, photodiode and many other signal processing functions where quantum well is not needed. The heterogeneous PIN waveguide structure can be for example InP/InGaAs/poly silicon, other IIV material combination suitable for lasers, detector, phase modulator and electro-absorption modulator are a variation of the proposed structure. Waveguide device configuration can be ring or disk resonator, Mach-Zhender interferometer, or a single pass waveguide with a variety of shapes such as spiral or corrugated shapes.

The heterogeneous PIN waveguide structure can be fabricated on multiple ways, one of the fabrication approach is to etch the upper cladding (35) and Quantum wells (45) of the III-V material on selective areas and deposit poly si or other type of silicon such as Amorphous silicon over the InGaAs layer. In this configuration the same lithography and etch steps could be used to fabricate the heterogeneous PIN waveguide structure for example modulator and detector as well as the III-V waveguide PIN structure on the III-V areas which are not etched to make lasers and amplifiers. The structure can then be protected with multi-layers of oxides including silicon nitride. Metal electrodes are used to interconnect PIN structures.

FIG. 5 shows cross section view of another embodiment of a III-V material waveguide structure in accordance with the present invention. In this configuration poly silicon waveguides are formed on top of III-V structure. The configuration could be fabricated as an example by depositing oxide layer over III-V material and then poly silicon is deposited over the oxide layer, poly si layer is etched to form si waveguide structure, for optical waveguide routing.

The structure of FIG. 5 can be further bonded to intermediary substrate, then III-V substrate is removed and III-V PIN waveguide structure is etched and metal contact interconnected. The III-V PIN waveguide structure can be evanescently coupled to the Poly si waveguide structure on the opposite side to form a three dimensional (3D) waveguide structure. The III-V PIN could be a laser diode and the poly si waveguide could be a passive optical coupling waveguide routing bus.

FIG. 6 shows cross section view of another embodiment of a III-V material waveguide structure in accordance with the present invention. Drawings are not to scale to highlight waveguide features. This configuration poly silicon waveguide are formed on top of III-V waveguide structure.

The configuration could be fabricated as an example by etching III-V waveguide structure (35) then deposit at least one oxide layer (30). The resulting wafer structure is flattened using chemical mechanical polishing (CMP) then poly silicon (31) is deposited over the oxide layer. Poly si layer is etched to form si waveguide structure (31), for optical waveguide routing.

Furthermore the structure on FIG. 6 could be either bonded to a temporary substrate to remove the main substrate and then solder bond the structure to a CMOS structure for example, and then remove the intermediary substrate and add punch though holes for metal interconnect. On other embodiment of this invention metal contact could be added to the structure on FIG. 6, and then upside down solder bonded to a CMOS structure, after that the III-V main substrate is removed. Further processing steps depend on the device and function. For example, silicon nitride could be used to hermitically seal the PIN diodes, and heat sink material could be added. Silicon carbide heat sink Pin diode and provide a transparent lower index cladding to the III-V material.

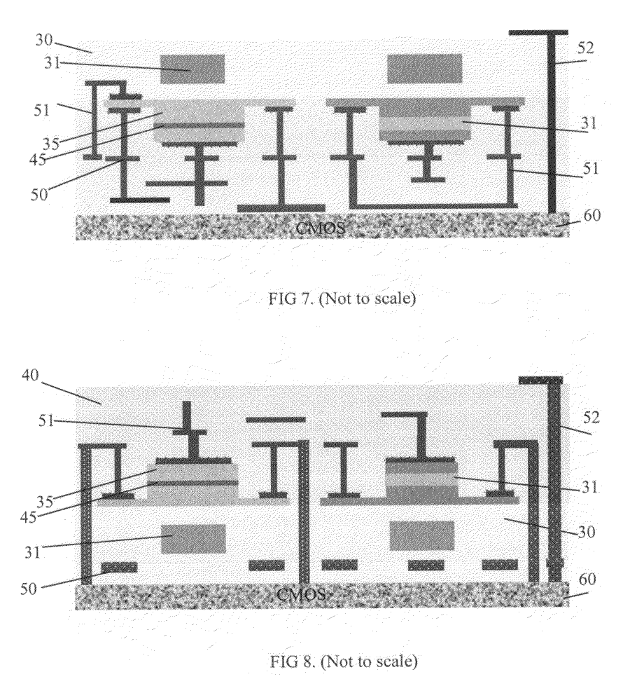

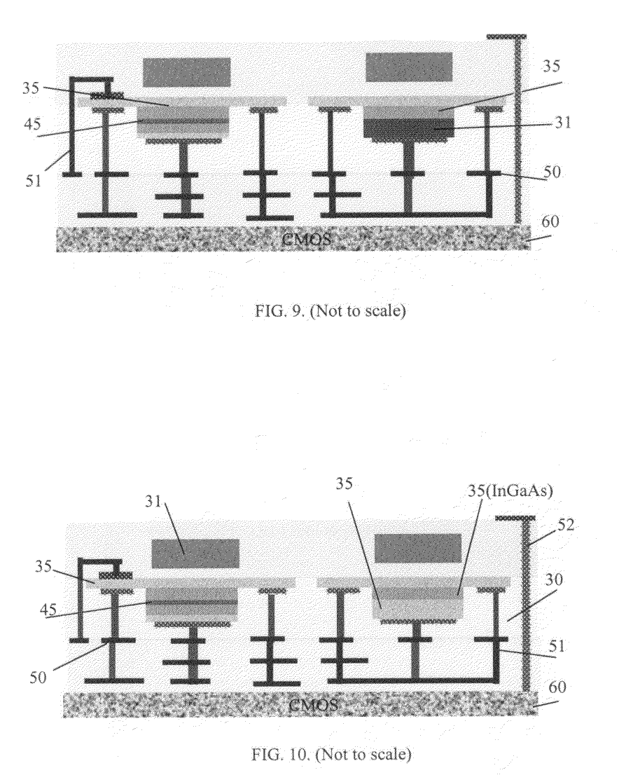

FIGS. 7, 8, 9 and 10 show a variety of embodiments of integrating III-V material waveguide structure, silicon waveguide structure and CMOS electronic structure (60) with metal interconnect (51 and 52) in accordance with the present invention. The three dimensional structure could be fabricated with one or more multi-steps process. In one embodiment, III-V wafer is etched to form a III-V waveguide structure, which is solder bonded to a CMOS structure. Optionally, poly silicon (p-Si) or amorphous silicon (a-Si) waveguides could be added on top of the structure. Metal contact (50) could be added to each structure prior to solder bonding or added post solder bonding depending on the preferred final waveguide structure configuration. Silicon nitride (40) could be used instead of oxide (30) as a passivation isolating cladding to the structure. It's possible to use also silicon carbide as a transparent low index cladding of the III-V/silicon waveguides for efficient heat sink of the PIN structure.

In another embodiment, as an example the structure could be fabricated by depositing oxide layer followed by poly silicon (p-Si) or amorphous silicon (a-Si) over III-V material and then p-Si/a-Si layer is etched to form waveguide structure, for optical waveguide routing. The structure is then solder bonded to a CMOS structure and the III-V substrate is released and removed to allow for process fabrication of a III-V waveguide structure. In another embodiment, the III-V structure is bonded to a temporary substrate to allow for process of III-V substrate release and fabrication of III-V waveguide structure. The resulting III-V waveguide structure is then bonded to CMOS structure. The III-V PIN waveguide structure would be evanescently coupled to the p-Si/a-Si waveguide structure on the opposite side to form a three dimensional (3D) waveguide structure. The poly si waveguide could be a passive optical coupling waveguide routing bus. The structure includes a verity of PIN waveguide structures, III-V PIN with Quantum well which could be a laser diode, III-V PIN waveguide structure without quantum well could be a modulator or detector, or heterogeneous PIN structure which could be a modulator, detector or any desired optical signal processing function, as well as a poly silicon PIN diode with can be a modulator or any type of optical signal processor.

Low index transparent heat sink such as PCB or Silicon carbide could be deposited on top of the laser and modulator diodes to improve heath management. Copper interconnect the PIN diodes could also be designed to improve heat sink.

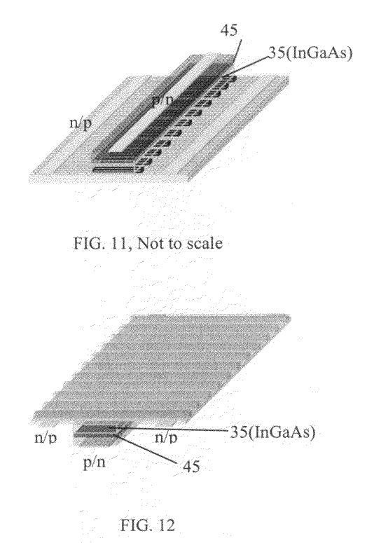

FIGS. 11 and 12 depicts two example embodiments of a III-V PIN diode structure having a distributed feedback Bragg grating (DFB). The DFB configuration of this invention requires no III-V re-growth. The grating is etched on one side and the metal contact electrodes are placed on the opposite side.

The waveguide structure on FIGS. 11 and 12 could be built with multiple methods of growth and etch. As an illustrative example, structure on FIG. 11 could be built by etching a grating on one side of the III-V structure than upside down solder bond the structure to a second substrate then release the III-V substrate after that the III-V waveguide structure is etched on the new surface. Further steps of oxide deposit and metal contact could be added. On a second illustrative example structure on FIG. 12 could be built by etching III-V waveguide structure on one side, bond the structure upside down to a second substrate then release the main III-V substrate, and then etch the grating Further process steps to protect the waveguide structure such as oxide and silicon nitride layers could be added.

Other varieties of laser cavities with gain section, phase section and Bragg section such as Distributed Bragg Grating (DBR) lasers could also be made with this original structure.

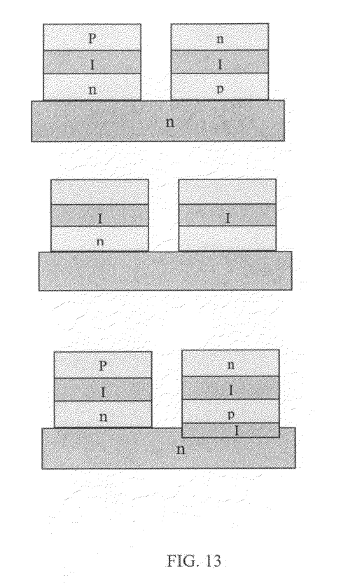

FIG. 13 depicts a possible PIN's integrated configurations for III-V material PIN waveguide structure, and as example silicon PIN structure on one comment substrate. As an example, a plurality of PIN-NIP with N substrate, PIN-PIN with N substrate, or PIN-NIP with intrinsic layer and N substrate etc.

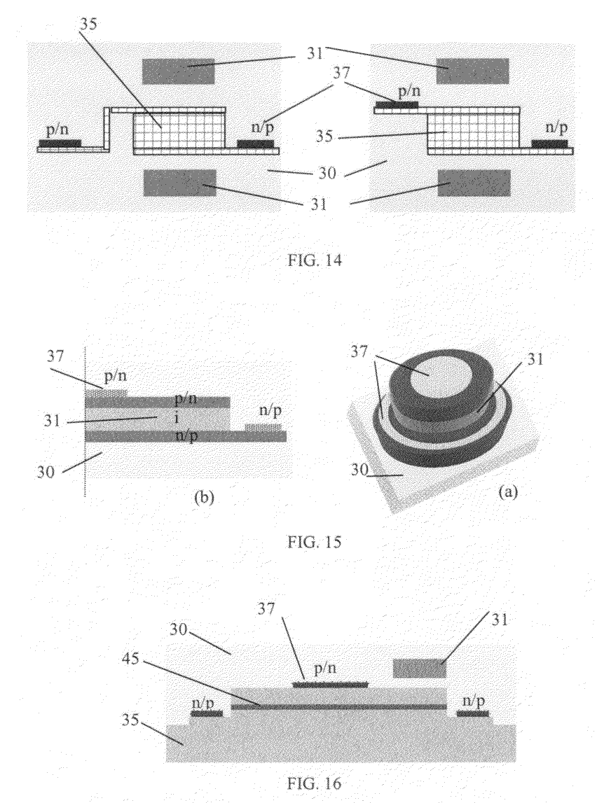

FIG. 14 depicts a possible electrode configuration for III-V material waveguide structure, which allows for optical evanescent coupling from both top and bottom of the III-V material waveguide structure at the same time it also eliminate the parasite capacitance that can be created in the configuration of electrodes on top of each others. On FIG. 14 the shape of the electrodes also allow for the electrodes to be placed away from the core optical mode which eliminate the need for thick cladding that my be required on the case of electrode on top the core waveguide to avoid optical loss from metal. These electrodes can be fabricated by multiple ways, e.g. by etching one side, bond the structure upside down release substrate, and then etch the opposite side and deposit electrodes. Or by growing and etching material structure with multiple steps growth and etch.

FIG. 15a shows a disk PIN diode resonator waveguide structure with top electrode on the center of the disk and the bottom electrode as an outer ring around the disk PIN diode. A cross section portion of the disk PIN waveguide resonator is shown on FIG. 15b. The structure electrical current injection can be optimized with multiple ways, as an example the diode polarity of the disk could be reversed on the center of the disk, because the electrical current is blocked on the center of the disk by the reversed polarity of the diode, the structure could be seen as a disk for optical signal and a ring for electrical signal.

On another embodiment a tunnel junction (TJ) could be implemented as a ring above or under the optical disk to confine the electrical current injection to a ring configuration while the optical signal confined by a disk resonator configuration.

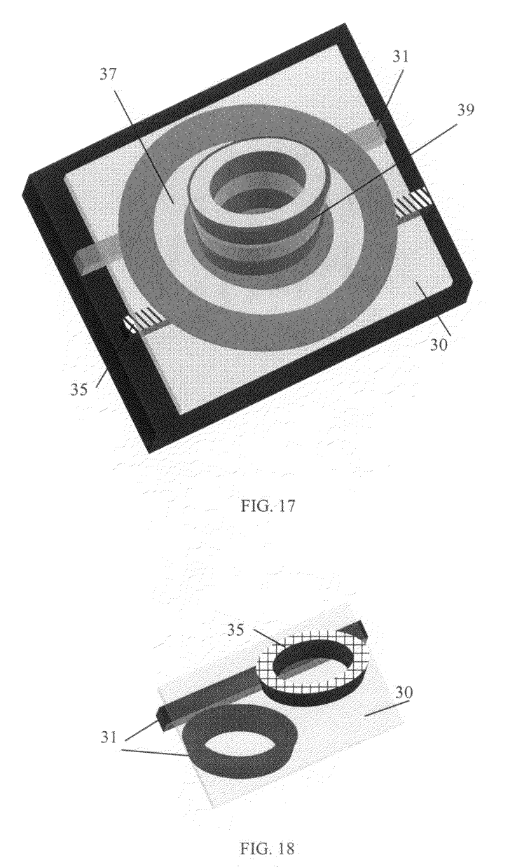

FIG. 16 shows across section of a III-V PIN diode disk resonator waveguide laser structure with p-Si/a-Si waveguide optical bus coupler on the top of it. The top electrode is on the center of the disk and the bottom electrode as an outer ring around the PIN diode disk. In another embodiment, the PIN diode disk structure can be etched from the back side to minimize the required current injection; the resulting structure is a ring resonator waveguide with a disk P/N layer and electrode.

FIG. 17 shows a perspective view of another embodiment of a three dimensional waveguide structure, combining III-V PIN waveguide structure (35) and p-Si/a-Si PIN diode on a ring configuration with electrode. III-V material waveguide structure optically coupled to silicon waveguide structure in accordance with the present invention, in this embodiment, example illustrates a PIN diode (39) poly-si modulator 3 dimensional waveguide structure integrated with III-V waveguide structure and poly-si coupler on a 3 dimensional structure.

FIG. 18 shows a perspective view of III-V material waveguide structure coupled to 3D silicon waveguide structure, in accordance with the present invention. Drawing not to scale to better illustrate waveguide features. III-V material waveguide structure coupled to silicon waveguide structure through an oxide low index gap layer. The poly-silicon layer (31) and III-V layer (35) waveguide structure are separated by oxide (30). The ring filter could be replaced by grating waveguide, Mack Zhender interferometer (MZI) etc.

As can be understood by expert on the art any other functions and devices could be integrated in the same way are covered by this invention. The Pin modulator could a ring or an MZI structure and the PIN could operate as forward and or reverse biased device. The waveguide I/O coupler the PIN modulator could be under, above or on the side of the modulator.

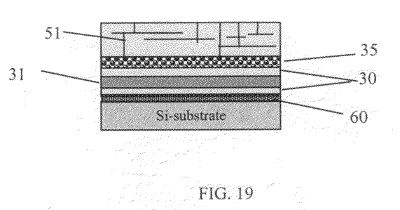

FIG. 19 shows another embodiment of integrated III-V material waveguide structure, silicon waveguide structure and CMOS electronic structure (60) with metal interconnect on the top of the structures in accordance with the present invention.

The optical waveguide structures that could be fabricated based on this invention includes and are not limited to electro-optic functions such as optical signal generation, modulation, amplification switching, and optical signal manipulation.

It's understood from the above waveguide formation examples that one can alter order or the waveguide formation on poly-silicon and III material to obtain a variety of 3 dimensional ply silicon and III-V material waveguide structure.

One could also etch trenches on III-V material and fill them with poly silicon to define the poly-silicon waveguide structure.
As is understood by experts on this art, the Poly si waveguide can be replaced by any other material with high index close to III-V material index, such as amorphous silicon or silicon nitride

The III-V material structure such as laser, modulator or photodiode are inherently hermetically sealed on the chip with silicon nitride layer on deposition during the chip process fabrication, this eliminate the need for external hermitic package of the chip. As is understood by experts on this art the laser cavity can have a varieties of configuration including single or multiple interconnected rings cavity, disk cavity, distributed feedback Bragg laser cavity (DFB), distributed Bragg reflective (DBR) mirrors, or a combination of any of the above etc.

Metal interconnects of the CMOS could be either placed above the CMOS and then the Optical waveguide structure interconnect from the top. Or in another embodiment of tight integration of CMOS and optical waveguide structure, the optical interconnect is placed on top of the optical waveguide structure, in this configuration the CMOS electronics and the optical waveguide structure are tightly close to each other.

It's also understood by people knowledgeable in this field that one can combine both poly-si waveguides and crystal silicon waveguide on the same structures/chip. Poly-si waveguides would be used for short lengths where design flexibility is needed and crystal silicon waveguide would be used for lengthy waveguide routing where optical loss need to be reduced.

As is understood by experts on this art the Poly si waveguide can be replaced by any other material with high index close to III-V material index, such as amorphous silicon or silicon nitride. Deposited amorphous silicon could be annealed to improve the optical quality and reduce defect to be closer to crystal silicon. On the other hand III-V material can be substituted by band gap materials which could convert electrical signal to optical signal or vise versa. Silicon carbide layers can be deposited for heat sink management on the optoelectronic circuit and silicon nitride could also be used for insulation and hermitticity.

Usually a thick oxide layer is required to confine the optical mode and prevent optical leakage. However, multiple alternating quarter wavelength thick layers of oxide and silicon could be used to provide a much better performance for optical isolation and heat dissipation. The optical waveguide structure proposed in this invention could be integrated with both bulk CMOS and Silicon on Insulator (SOI) CMOS.

It's understood by expert on the field that other variations of this innovation are considered part of this invention.

The invention claimed is:

1. An optoelectronic circuit comprising: A multi-layers heterogonous positive-intrinsic-negative (PIN) structure; and one or more of the following structures: III-V material positive-intrinsic-negative (PIN) layers diode structure, poly-silicon-Si/amorphous-silicon PIN diode layers structure and passive poly-silicon-Si/amorphous-silicon layers structure on the same substrate.

2. Claim 1 said multi-layers heterogeneous positive-intrinsic-negative (PIN) structure where the P layer made of poly silicon and N layer of III-V material and visa versa.

3. Claim 1 where the multi-layers heterogeneous PIN waveguide structure can be for example InP/InGaAs/poly-silicon.

4. Claim 1 multi-layers heterogeneous PIN waveguide structure where the metallization electrodes for the bottom and top layers are away from the waveguide structure at same level except for the a least one thin layer that provide ohmic contact between the said top PIN layer and the said top metal electrode which is a away from the PIN waveguide structure.

5. Claim 1 where the multi-layers structure comprising at least PIN layers of III-V material, at least one oxide layer and at least a multi-layers PIN of poly/amorphous silicon diodes and at least one silicon carbide layer on the same substrate.

6. Claim 1 where the said multi-layers PIN of poly/amorphous silicon diodes is a multi-layers of poly/amorphous silicon waveguides on the same substrate.

7. Claim 1 where the said multi-layers structure comprising PIN layers of III-V material, at least one oxide layer and at least a multi-layers PIN of poly/amorphous silicon diodes waveguide structure fabricated with a single mask and one or more etch steps.

8. An optoelectronic circuit comprising a multi-layers III-V material PIN diode structure adjacent side by side to a multi-layers PIN of poly/amorphous silicon diode structure and a poly silicon structure on the same substrate.

9. Claim 8 where said multi-layers PIN of III-V material adjacent side by side to said silicon waveguide structure on the same substrate.

10. Claim 8 where said multi-layers PIN diode has a form of a disk with reversed polarity in the center of the disk, where the structure behave as an disk optical resonator and as a ring shape electrical current injection. Where the said ring current injection can also be achieved with ring BJT current concentration.

11. Claim 8 where said side by side multi-layers PIN structure is a plurality of PIN-NIP with N substrate, PIN-PIN with N substrate, or PIN-NIP with intrinsic layer and N substrate and visa versa.

12. Claim 8 where said multi-layers side by side structures are such that same lithography, etch and metallization steps can be used to fabricate the waveguide structures of varies multi-layers PIN materials.

13. Claim 8 where said multi-layers PIN of III-V material waveguide structure is such that a Bragg grating structure on one side of the PIN layers, and a waveguide structure and metal electrodes on the opposite side of the PIN layers structure.

14. Claim 8 multi-layers PIN of III-V material waveguide structure where the metallization electrodes for the bottom and top layers are away from the waveguide structure at same level except for the a least one thin layer that provide ohmic contact between the said top PIN layer and the said top metal electrode which is away from the PIN waveguide structure.

15. An optoelectronic structure where the semiconductor structure is made of multi-layers structure comprising at least PIN layers of III-V material, oxide layers, at least a multi-layers PIN of poly silicon diode and active layer containing CMOS electronics structure and a plurality of multi-layers of metallization between said CMOS electronic and multi-layers PIN structure and between CMOS and top metal contact layers, and at least one silicon carbide layer, and at least one silicon nitride layer.

16. Claim 15 where the said heterogeneous positive-intrinsic-negative (PIN) structure is solder bonded to said CMOS electronics structure

17. Claim 15 where the said PIN layers of III-V material adjacent side by side to said silicon waveguide on the same substrate is bonded to a CMOS structure

18. Claim 15 where the said multi-layers structure comprising at least PIN layers of III-V material, oxide layers and at least a multi-layers PIN of poly/amorphous silicon diodes on the same substrate is solder bonded to a CMOS structure.

19. Claim 15 where the said multi-layers PIN of poly/amorphous silicon diodes is a multi-layers of poly/amorphous silicon waveguides on the same substrate.

20. Claim 15 where the said multi-layers structure comprising a PIN layers of III-V material, at least one oxide layer and at least a multi-layers PIN of poly silicon diodes waveguide structure fabricated with a single mask and one or more of etch steps.
